(19) United States
(12) Patent Application Publication
(10) Pub. No.: US 2025/0368921 A1
(43) Pub. Date: Dec. 4, 2025

(54) ELECTRONIC DEVICE MANUFACTURING AQUEOUS SOLUTION, METHOD FOR MANUFACTURING RESIST PATTERN AND METHOD FOR MANUFACTURING DEVICE

(71) Applicant: Merck Patent GmbH, Darmstadt (DE)

(72) Inventors: Kazuma Yamamoto, Shizuoka (JP); Maki Ishii, Shizuoka (JP); Hiroshi Yanagita, Shizuoka (JP)

(21) Appl. No.: 19/243,592

(22) Filed: Jun. 19, 2025

Related U.S. Application Data
(63) Continuation of application No. PCT/EP2023/086794, filed on Dec. 20, 2023.

(30) Foreign Application Priority Data
Dec. 26, 2022 (JP) 2022-208546

(51) Int. Cl. C11D 1/14; C11D 1/22; C11D 3/20; G03F 7/00; G03F 7/40; H01L 21/02; H01L 21/027

(52) U.S. Cl. CPC C11D 1/143; C11D 1/22; C11D 3/2044; G03F 7/40; G03F 7/70033; H01L 21/02057; H01L 21/027

(57) ABSTRACT

An electronic device manufacturing aqueous solution includes a sulfonic acid derivative (A); a solvent (B); and a hydroxy-containing compound (C), wherein the sulfonic acid derivative (A) is represented by the formula (a) as defined herein.

### CROSS-REFERENCE TO RELATED APPLICATIONS

This application is a Continuation under 35 USC § 111(a) of International Patent Application No. PCT/EP2023/086794 filed Dec. 20, 2023, which claims priority to the JP Application no. 2022-208546 filed Dec. 26, 2022. The entire contents of these applications are incorporated herein by reference in their entirety.

### BACKGROUND OF THE INVENTION

### Technical Field

The present invention relates to an electronic device manufacturing aqueous solution, a method for manufacturing a resist pattern and a method for manufacturing a device.

### Background Art

In recent years there has been an increasing need for high integration of large scale integration (LSI), which requires pattern refining. In order to respond such needs, lithography processes using KrF excimer laser, ArF excimer laser, extreme ultraviolet, X-ray of short wavelength, electron beam and the like have been put to practical use. In order to respond to such refining of resist patterns, and also in order for the use of photosensitive resin compositions as a resist during refining processing, such processes require having high resolution. Finer patterns can be formed through short wavelength light exposure, but yield becomes problematic with an extremely fine structure due to fine pattern collapse and the like.

JP 2012-198456 A discloses that pattern collapse etc. are suppressed by a rinse liquid containing a sulfonic acid compound and a nonionic surfactant. JP 2014-219577 A discloses that suppression of pattern collapse and good properties in melting are obtained by use of a rinse liquid containing a nonionic surfactant.

### SUMMARY OF THE INVENTION

### Problems to be Solved by the Invention

The present inventors considered that there are one or more problems still needing improvements. Examples of these include the following: reducing defects in fine resist patterns; suppressing bridge formation in resist patterns; preventing resist pattern collapse in fine resist patterns; suppressing resist pattern width non-uniformity; reducing the residue after removing an electronic device manufacturing aqueous solution; reducing the surface tension of an electronic device manufacturing aqueous solution; providing an electronic device manufacturing aqueous solution with low handling risk; providing an electronic device manufacturing aqueous solution having good storage stability (for example, long-term storage); and providing an electronic device manufacturing aqueous solution with less impact given to resist patterns.

The present invention has been made based on the technical background as described above and provides an electronic device manufacturing aqueous solution.

### Means for Solving the Problems

The electronic device manufacturing aqueous solution according to the present invention comprises:
a sulfonic acid derivative (A);
a solvent (B); and
a hydroxy-containing compound (C),
wherein
the sulfonic acid derivative (A) is represented by the formula (a):

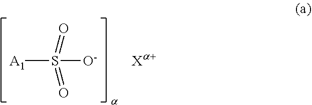

wherein
   A₁ is a C₃₋₃₀ hydrocarbon group, and the hydrocarbon group can be substituted with a halogen;
   α is 1 or 2; and
   X^{α+} is H⁺, NH₄⁺ or an a-valent metal ion,
the solvent (B) comprises water, and
the hydroxy-containing compound (C) is represented by the formula (c):

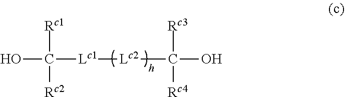

wherein
   R^{c1}, R^{c2}, R^{c3} and R^{c4} are each independently hydrogen, fluorine or C₁₋₅ alkyl;
   L^{c1} and L^{c2} are each independently C₁-20 alkylene, C₅₋₂₀ cycloalkylene, C₂₋₄ alkenylene, C₂-4 alkynylene or C₆₋₂₀ arylene, and these groups can be substituted with fluorine, C₁₋₅ alkyl or hydroxy; and
   h is 0, 1 or 2.

The method for manufacturing a resist pattern according to the present invention uses the above-mentioned electronic device manufacturing aqueous solution.

The method for manufacturing a device according to the present invention comprises the above-mentioned method for manufacturing a resist pattern.

### Effects of the Invention

Using the electronic device manufacturing aqueous solution according to the present invention, it is possible to expect one or more of the following effects.

It is possible to reduce defects in fine resist patterns. It is possible to suppress the formation of bridges in the resist patterns. It is possible to prevent the resist pattern collapse in fine resist patterns. It is possible to suppress the resist pattern width non-uniformity. It is possible to reduce the residue after removing an electronic device manufacturing aqueous solution. It is possible to reduce the surface tension of an electronic device manufacturing aqueous solution. It is possible to reduce the handling risk of an electronic device manufacturing aqueous solution. It is possible to make good storage stability of an electronic device manufacturing aqueous solution. It is possible to reduce the impact that an electronic device manufacturing aqueous solution gives to resist patterns.

### BRIEF DESCRIPTION OF THE DRAWINGS

FIG. 1 is a schematic illustration showing the state of rinsing resist walls.

### DETAILED DESCRIPTION OF THE INVENTION

### Mode for Carrying Out the Invention

Embodiments of the present invention are described below in detail.

### Definitions

Unless otherwise specified in the present specification, the definitions and examples described in this paragraph are followed.

The singular form includes the plural form and “one” or “that” means “at least one”. An element of a concept can be expressed by a plurality of species, and when the amount (for example, mass % or mol %) is described, it means sum of the plurality of species.

“And/or” includes a combination of all elements and also includes single use of the element.

When a numerical range is indicated using “to” or “-”, it includes both endpoints and units thereof are common. For example, 5 to 25 mol % means 5 mol % or more and 25 mol % or less.

The descriptions such as “C_{x-y}”, “Cₓ-C_{y}” and “Cₓ” mean the number of carbons in a molecule or substituent. For example, C₁₋₆ alkyl means an alkyl chain having 1 or more and 6 or less carbons (methyl, ethyl, propyl, butyl, pentyl, hexyl etc.).

When polymer has plural types of repeating units, these repeating units copolymerize. These copolymerization may be any of alternating copolymerization, random copolymerization, block copolymerization, graft copolymerization, or a mixture thereof. When polymer or resin is represented by a structural formula, n, m or the like that is attached next to parentheses indicate the number of repetitions.

Celsius is used as the temperature unit. For example, 20 degrees means 20 degrees Celsius.

The additive refers to a compound itself having a function thereof (for example, in the case of a base generator, a compound itself that generates a base). An embodiment in which a compound is dissolved or dispersed in a solvent and added to a composition is also possible. As one embodiment of the present invention, it is preferable that such a solvent is contained in the composition according to the present invention as the solvent (B) or another component.

### Electronic Device Manufacturing Aqueous Solution

The electronic device manufacturing aqueous solution according to the present invention comprises a sulfonic acid derivative (A) (hereinafter referred also to as the component (A), and the same applies to the other components), a solvent (B) and a hydroxy-containing compound (C).

Here, the electronic device manufacturing aqueous solution is one used in the process of manufacturing an electronic device. It can be one used in the manufacturing process of an electronic device and can be one being removed or lost in the course of the process. Examples of the electronic device include display devices, LED and semiconductor devices. The electronic device manufacturing aqueous solution is preferably a semiconductor substrate manufacturing aqueous solution; more preferably a semiconductor substrate manufacturing process cleaning liquid; further preferably a lithography cleaning liquid; and furthermore preferably a resist pattern cleaning liquid. The electronic device manufacturing aqueous solution that is a semiconductor substrate manufacturing aqueous solution can also be said to be a semiconductor substrate manufacturing aqueous solution consisting only of the electronic device manufacturing aqueous solution of the present invention.

As another embodiment of the present invention, the electronic device manufacturing aqueous solution can be a rinse composition used for rinsing an exposed and developed resist pattern.

### Sulfonic Acid Derivative (A)

The sulfonic acid derivative (A) used in the present invention is represented by the formula (a):

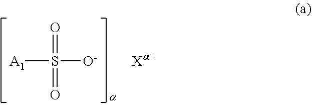

where
   A₁ is a C₃₋₃₀ hydrocarbon group (preferably C₈₋₂₈; more preferably C₁₂₋₂₈; further preferably C₁₂₋₂₅; further more preferably C₁₂₋₂₀). The hydrocarbon group can be substituted with a halogen or unsubstituted (preferably unsubstituted). A₁ is preferably alkyl, phenyl-substituted alkyl or alkyl-substituted phenyl (more preferably alkyl or alkyl-substituted phenyl; further preferably alkyl). The alkyl contained in A₁ can be linear, branched or cyclic (preferably linear or branched; more preferably linear).
   α is 1 or 2 (preferably 1).
   X^{α+} is H⁺, NH₄⁺ or an a-valent metal ion. X^{α+} is preferably H⁺, NH₄⁺, a lithium ion, a sodium ion, a potassium ion, a magnesium ion (more preferably H⁺ or NH₄⁺; further preferably H⁺). For example, when X^{α+} is Mg²⁺, two groups bonding a sulfo group to A₁ in the parentheses to which a is attached are present, and these groups ionically bond to Mg²⁺. In an aqueous solution, some or all of these ionize.

The component (A) is preferably represented by the formula (a-1) or (a-2). In one preferred embodiment, the component (A) is represented by the formula (a-2).

The formula (a-1) is as follows:

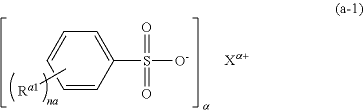

where
   α and X^{α+} are as described above;
   na is 1 or 2, preferably 1; and
   R^{a1} is C₁₋₂₀ alkyl (preferably C₃₋₂₀; more preferably C₁₀₋₂₀). Provided that when na is 2, R^{a1} can be identical or different, but the total number of carbon atoms is 20 or less. The alkyl of R^{a1} is preferably linear, branched or cyclic (more preferably linear or branched; further preferably linear).

In another preferred embodiment of the present invention, the component (A) is represented by the formula (a-1).

The formula (a-1) includes, for example, decylbenzenesulfonic acid, undecylbenzenesulfonic acid, dodecylbenzenesulfonic acid, tridecylbenzenesulfonic acid, tetradecylbenzenesulfonic acid, pentadecylbenzenesulfonic acid, hexadecylbenzenesulfonic acid, heptadecylbenzenesulfonic acid, octadecylbenzenesulfonic acid, nonadecylbenzenesulfonic acid, and the following compounds, etc.

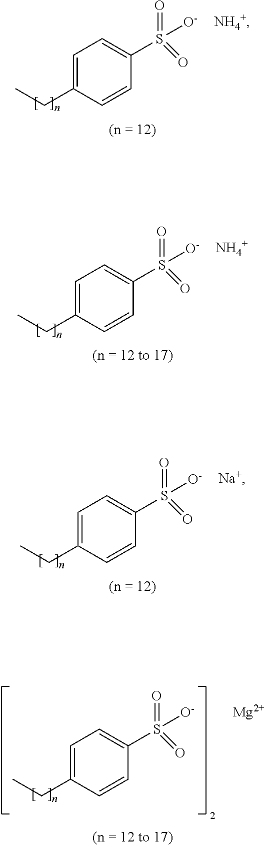

The formula (a-2) is as follows:

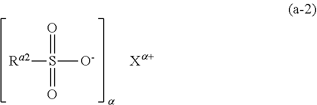

wherein
   α and X^{α+} are as described above; and
   R^{a2} is C₃₋₂₀ alkyl (preferably C₈₋₂₀; more preferably C₁₀₋₂₀; further preferably C₁₀₋₁₉; further more preferably C₁₃₋₁₉). The alkyl of R^{a2} is preferably linear, branched or cyclic (more preferably linear or branched; further preferably linear).

The formula (a-2) includes, for example, decane sulfonic acid, undecane sulfonic acid, dodecane sulfonic acid, tridecane sulfonic acid, tetradecane sulfonic acid, pentadecane sulfonic acid, hexadecane sulfonic acid, heptadecane sulfonic acid, octadecane sulfonic acid, nonadecane sulfonic acid and the following compounds, etc.

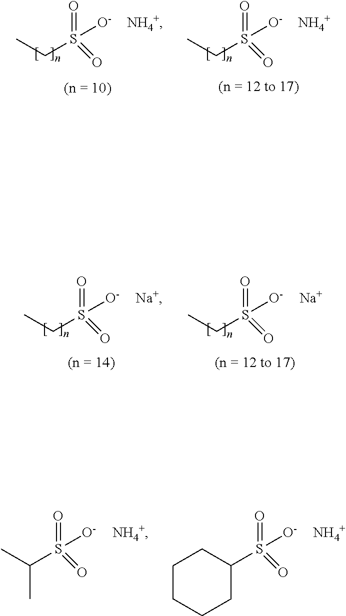

One of the effects of the electronic device manufacturing aqueous solution according to the present invention is that it suppresses defects in the resist pattern after development. Although not to be bound by theory, it can be thought that since the component (A) has a sulfonic acid-derived moiety, it is possible to ensure the dispersibility in an aqueous solution, while lower the surface tension due to the presence of other moieties. It can be thought that since the component (A) has a high affinity with water in the electronic device manufacturing aqueous solution and is often present on the water side, it does not stay in the photosensitive resin pattern and reduces the risk of causing defects in the photosensitive resin pattern.

The component (A) can be one type or a mixture of any two or more types.

The content of the component (A) is preferably 0.001 to 10 mass % (more preferably 0.01 to 5 mass %; further preferably 0.01 to 1 mass %; further more preferably 0.02 to 0.4 mass %) based on the electronic device manufacturing aqueous solution.

### Solvent (B)

The solvent (B) comprises water. The water is preferably a deionized water.

Considering that it is used in the electronic device manufacturing process, as the more preferable embodiment, in semiconductor manufacturing process, the solvent (B) is preferably one having few impurities. The impurity concentration of the solvent (B) is preferably 1 ppm or less (more preferably 100 ppb or less, and further preferably 10 ppb or less).

The content of water based on the solvent (B) is preferably 90 to 100 mass % (more preferably 98 to 100 mass %; further preferably 99 to 100 mass %; further more preferably 99.9 to 100 mass %). In a preferred embodiment of the present invention, the solvent (B) consists substantially only of water. However, an embodiment in which an additive is dissolved and/or dispersed in a solvent other than water (for example, a surfactant) and contained in the electronic device manufacturing aqueous solution of the present invention is accepted as a preferred embodiment of the present invention. In a further preferred embodiment of the present invention, the content of the water contained in the solvent (B) is 100 mass %.

As exemplified embodiments of the solvent (B) excluding water, for example, cyclohexanone, cyclopentanone, propylene glycol monomethyl ether (PGME), propylene glycol monoethyl ether, propylene glycol monopropyl ether, propylene glycol monobutyl ether, propylene glycol dimethyl ether, propylene glycol diethyl ether, propylene glycol 1-monomethyl ether 2-acetate (PGMEA), propylene glycol monoethyl ether acetate, propylene glycol monopropyl ether acetate, γ-butyrolactone, ethyl lactate, or any mixture of any of these are preferable. These are preferable in terms of storage stability of the solution. These solvents can be also used as any mixture of any two or more.

The content of the solvent (B) is preferably 80 to 99.999 mass % (more preferably 90 to 99.99 mass %; further preferably 95 to 99.99 mass %; further more preferably 98 to 99.99 mass %) based on the electronic device manufacturing aqueous solution.

The content of the water contained in the solvent (B) is preferably 80 to 99.99 mass % (more preferably 90 to 99.99 mass %; further preferably 95 to 99.99 mass %; further more preferably 98 to 99.99 mass %) based on the electronic device manufacturing aqueous solution.

### Hydroxy-Containing Compound (C)

The hydroxy-containing compound (C) used in the present invention is represented by the formula (c):

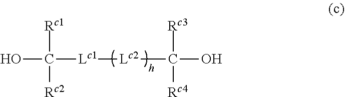

wherein
   R^{c1}, R^{c2}, R^{c3} and R^{c4} are each independently hydrogen, fluorine or C₁₋₅ alkyl (preferably each independently hydrogen, fluorine, methyl, ethyl, t-butyl or isopropyl; more preferably each independently hydrogen, methyl or ethyl); and
   Lc1 and Lc2 are each independently C₁₋₂₀ alkylene, C₅₋₂₀ cycloalkylene, C₂₋₄ alkenylene, C₂₋₄ alkynylene or C₆₋₂₀ arylene.

Optionally, these groups can be substituted with fluorine, C₁₋₅ alkyl or hydroxy. Here, alkenylene means a divalent hydrocarbon group having one or more double bonds, and alkynylene means a divalent hydrocarbon group having one or more triple bonds. Preferably, Lc1 and Lc2 are each independently fluorine-substituted C₁₋₅ alkylene, C₂₋₄ alkenylene, C₂₋₄ alkynylene or phenylene (C₆ arylene); more preferably fluorine-substituted C₂₋₄ alkylene, C₂ alkenylene, C₂ alkynylene or phenylene; further more preferably C₂ alkenylene or C₂ alkynylene; most preferably C₂ alkynylene (acetylene). It is possible to obtain the effects of the present invention even without using any fluorine-containing component.
h is 0, 1 or 2 (preferably 0 or 1; more preferably 0).

Exemplified embodiments of the hydroxy-containing compound (C) include 3-hexyne-2,5-diol, 2,5-dimethyl-3-hexyne-2,5-diol, 3,6-dimethyl-4-octyne-3, 6-diol, 1,4-butynediol, 2,4-hexadiyn-1,6-diol, 1,4-butanediol, 2,2,3,3-tetrafluoro-1,4-butanediol, 2,2,3,3,4,4,5,5-octafluoro-1,6-hexanediol, cis-1,4-dihydroxy-2-butene, 1,4-benzenedimethanol, 4,7-dihydroxy-2,4,7,9-tetramethyl-5-decyne, and combinations thereof.

The content of the hydroxy-containing compound (C) is preferably 0.001 to 10 mass % (more preferably 0.005 to 5 mass %; further preferably 0.01 to 1 mass %; further more preferably 0.01 to 0.1 mass %) based on the electronic device manufacturing aqueous solution.

Although not to be bound by theory, it can be thought that by containing the component (C), it is possible to suppress the aggregation of the component (A) in the manufacturing process of electronic devices (for example, a resist pattern cleaning process).

The electronic device manufacturing aqueous solution according to the present invention essentially comprises the components (A), (B) and (C) described above, but can contain further compounds as necessary. This is explained in detail below. The components other than (A) to (C) in the entire composition (in the case of plurality, the sum thereof) are preferably 0 to 10 mass % (more preferably 0 to 5 mass %; further preferably 0 to 3 mass %; further more preferably 0.0001 to 1 mass %) based on the electronic device manufacturing aqueous solution. It is also a preferred embodiment of the present invention that the electronic device manufacturing aqueous solution according to the present invention does not contain any components other than (A) to (C) (0 mass %).

### Nitrogen-Containing Compound (D)

The electronic device manufacturing aqueous solution according to the present invention can further comprise a nitrogen-containing compound (D). The nitrogen-containing compound (D) may have 1 or more nitrogen in the compound.

By combining the component (D) in the electronic device manufacturing aqueous solution according to the present invention, pattern collapse can be further suppressed. Although not to be bound by theory, it can be thought that the impact of the component (A) to resist patterns can be reduced by containing the nitrogen-containing compound (D).

Examples of the component (D) include the followings:
(i) ammonia,
(ii) primary aliphatic amines having 1 to 16 carbon atoms and derivatives thereof (for example, methylamine, ethylamine, isopropylamine, n-butylamine, tert-butylamine, cyclohexylamine, ethylenediamine, tetraethylenediamine, etc.),
(iii) secondary aliphatic amines having 2 to 32 carbon atoms and their derivatives (for example, dimethylamine, diethylamine, methylethylamine, dicyclohexylamine, N,N-dimethylmethylenediamine, etc.),
(iv) tertiary aliphatic amines having 3 to 48 carbon atoms and derivatives thereof (for example, trimethylamine, triethylamine, tripropylamine, dimethylethylamine, tricyclohexylamine, N, N,N′, N′-tetramethylethylenediamine, N,N,N′, N′-tetraethyl-ethylenediamine, N,N,N′, N″,N″-pentamethyl-diethylenetriamine, tris[2-(dimethylamino)ethyl]amine, tris[2-(2-methoxyethoxy)ethyl]amine, etc.),
(v) aromatic amines having 6 to 30 carbon atoms and derivatives thereof (for example, aniline, benzylamine, naphthylamine, N-methylaniline, 2-methylaniline, 4-aminobenzoic acid, phenylalanine, etc.), and
(vi) heterocyclic amines having 5 to 30 carbon atoms and derivatives thereof (for example, pyrrole, oxazole, thiazol, imidazole, 4-methylimidazole, pyridine, methylpyridine, butylpyridine, etc.).

The component (D) is preferably selected from the group consisting of (i), (ii) and (iv), and more preferably selected from the group consisting of ammonia, n-butylamine, ethylenediamine, triethylamine, tripropylamine and N,N,N′,N′-tetraethylethylenediamine.

The molecular weight of the component (D) is preferably 17 to 500 (more preferably 17 to 150; further preferably 60 to 143).

The content of the component (D) is preferably 0.0001 to 1 mass % (more preferably 0.0005 to 0.5 mass %; further preferably 0.0005 to 0.1 mass %) based on the electronic device manufacturing aqueous solution. It is also an embodiment of the present invention that the electronic device manufacturing aqueous solution according to the present invention does not contain any component (D).

### Surfactant (E)

The electronic device manufacturing aqueous solution according to the present invention can further comprise a surfactant (E). The surfactant (E) is useful for improving coatability and solubility. Here, the component (E) is different one from the above-mentioned components (A), (C) and (D).

Examples of the component (E) include polyoxyethylene alkyl ether compounds, such as polyoxyethylene lauryl ether, polyoxyethylene stearyl ether and polyoxyethylene oleyl ether, polyoxyethylene alkylaryl ether compounds, such as polyoxyethylene octylphenyl ether and polyoxyethylene nonylphenol ether, polyoxyethylene/polyoxypropylene block copolymer compounds, sorbitan fatty acid ester compounds, such as sorbitan monolaurate, sorbitan monopalmitate, sorbitan monostearate, sorbitan trioleate and sorbitan tristearate, polyoxyethylene sorbitan fatty acid ester compounds, such as polyoxyethylene sorbitan monolaurate, polyoxyethylene sorbitan monopalmitate, polyoxyethylene sorbitan monostearate and polyoxyethylene sorbitan tristearate.

Fluorosurfactants such as trade names Eftop EF301, EF303, EF352 (Tohkem Products), trade names Megaface F171, F173, R-08, R-30, R-2011 (DIC), Fluorad FC430, FC431 (Sumitomo 3M), and trade names AsahiGuard AG710, Surflon S-382, SC101, SC102, SC103, SC104, SC105, SC106 (AGC); and organosiloxane polymer KP341 (Shin-Etsu Chemical) or the like are exemplified.

The content of the component (E) is preferably 0.001 to 5 mass % (more preferably 0.005 to 1 mass %; further preferably 0.01 to 0.1 mass %) based on the electronic device manufacturing aqueous solution.

It is also a preferred embodiment of the present invention to contain no component (E).

### Additive (F)

The electronic device manufacturing aqueous solution according to the present invention can further comprise an additive (F). In the present invention, the additive (F) comprises an acid, a base, a germicide, an antibacterial agent, a preservative or a fungicide. The acid in the additive (F) is different from the component (A). The base in the additive (F) is different from the component (D). The additive (F) more preferably comprises an antibacterial agent (further preferably consists only of an antibacterial agent).

The acid or base can be used to adjust the pH value of the treating liquid and improve the solubility of additive components. Examples of the acid include aromatic carboxylic acids.

The component (F) can comprise an antibacterial agent, a bactericidal agent, a preservative or a germicide, if necessary. These chemicals are used to prevent bacteria or fungi from propagating over time. Examples of these chemicals include alcohols such as phenoxyethanol, and isothiazolone. Bestcide (Nippon Soda) is a more effective antibacterial agent, bactericidal agent and germicide.

The content of the additive (F) is preferably 0.0001 to 10 mass % (more preferably 0.0001 to 0.1 mass %; further preferably 0.0002 to 0.001 mass %) based on the electronic device manufacturing aqueous solution. It is also a preferred embodiment of the present invention to contain no additive (F).

The electronic device manufacturing aqueous solution according to the present invention can be filtered with a filter to remove impurities and/or insolubles after dissolving its components.

### Method for Manufacturing a Resist Pattern

The present invention also provides a method for producing a resist pattern using the above-mentioned electronic device manufacturing aqueous solution. The photosensitive resin composition (resist composition) used in the method may be either a positive type or a negative type; the positive type is more preferable. A typical method for manufacturing a resist pattern to which the electronic device manufacturing aqueous solution according to the present invention is applied comprises the following steps:
(1) applying a photosensitive resin composition on a substrate with or without one or more intervening layers, to form a photosensitive resin layer;
(2) exposing the photosensitive resin layer to radiation;
(3) developing the exposed photosensitive resin layer; and
(4) cleaning the developed layer with the above-mentioned electronic device manufacturing aqueous solution.

Hereinafter, details are explained. First, a photosensitive resin composition is applied (for example, laminated) above a substrate such as a silicon substrate or a glass substrate, which has been pretreated as necessary, thereby forming a photosensitive resin layer. Any publicly known method can be used for laminating, but a coating method such as spin coating is suitable. The photosensitive resin composition can be laminated directly on the substrate or can be laminated with one or more intervening layers (for example, BARC). Further, an anti-reflective coating (for example, TARC) can be laminated above the photosensitive resin layer (opposite to the substrate). Layers other than the photosensitive resin layer are described later. Forming an anti-reflective coating above or under the photosensitive resin film makes it possible to improve the cross-sectional shape and the exposure margin.

Typical examples of the positive type or negative type photosensitive resin composition used in the method for manufacturing a resist pattern of the present invention include one comprising a quinonediazide-based photosensitizer and an alkali-soluble resin, and a chemically amplified type photosensitive resin composition. From the viewpoint of forming a fine resist pattern having high resolution, a chemically amplified type photosensitive resin composition is preferable, and examples thereof include a chemically amplified type PHS-acrylate hybrid-based EUV resist composition. It is more preferable that these are positive type photosensitive resin compositions.

Although not to be bound by theory, the inventors thought as follows. Resist compositions used for EUV exposure are intended to form finer resist patterns, but there is a problem that due to the characteristics of the resist composition (for example, high hydrophobicity), defects are more likely to occur in the formed resist patterns. It can be thought that by using the aqueous solution of the present invention, it is possible to clean fine resist patterns while preventing such defects.

Examples of the quinonediazide-based photosensitizer used in the positive type photosensitive resin composition comprising the quinonediazide-based photosensitizer and the alkali-soluble resin include 1,2-benzoquinonediazide-4-sulfonic acid, 1,2-naphthoquinonediazide-4-sulfonic acid, 1,2-naphthoquinonediazido-5-sulfonic acid, esters or amides of these sulfonic acids, or the like, and examples of the alkali-soluble resin include polyvinyl phenol, polyvinyl alcohol, copolymer of acrylic acid or methacrylic acid, or the like.

As the chemically amplified type photosensitive resin composition, a positive type chemically amplified photosensitive resin composition comprising a compound (photoacid generator) that generates an acid by irradiation with radiation and resin whose polarity is increased by the action of an acid generated from the photoacid generator and whose solubility in a developer changes between the exposed portion and the unexposed portion, or a negative type chemically amplified photosensitive resin composition comprising an alkali-soluble resin, a photoacid generator and a crosslinking agent, in which crosslinking of the resin occurs by the action of the acid and the solubility in a developer changes between the exposed portion and the unexposed portion can be mentioned.

As the resin whose polarity is increased by the action of the acid and whose solubility in a developer changes between the exposed portion and the unexposed portion, resin having a group at the main chain or side chain of the resin, or both the main chain and the side chain of the resin, which decomposes by the action of the acid to generate an alkali-soluble group can be mentioned. Typical examples thereof include polymer in which an acetal group or a ketal group is introduced as a protective group into a hydroxystyrene-based polymer (PHS) (for example, JP H2-19847 A), and a similar polymer in which a t-butoxy carbonyloxy group or a p-tetrahydropyranyloxy group is introduced as an acid-decomposable group (JP H2-209977 A, etc.), and the like.

The photoacid generator can be any compound that generates an acid by irradiating radiation, and examples thereof include onium salts such as diazonium salts, ammonium salts, phosphonium salts, iodonium salts, sulfonium salts, selenonium salts and arsonium salts, organic halogen compounds, organometallic compounds/organic halides, photoacid generators having an o-nitrobenzyl type protective group, compounds capable of photolysis to generate a sulfonic acid represented by iminosulfonate or the like, disulfon compounds, diazoketosulfone compounds, diazodisulfone compounds, and the like. Further, compounds in which these groups or compounds capable of generating an acid by light are introduced into the main chain or the side chain of polymer can also be used.

The above-mentioned chemically amplified type photosensitive resin composition can further comprise, if necessary, an acid-decomposable and dissolution inhibiting compound, a dye, a plasticizer, a surfactant, a photosensitizer, an organic basic compound, a compound that promotes solubility in a developer, and the like.

The photosensitive resin composition is, for example, applied on a substrate by a suitable coating apparatus such as a spinner or coater by means of a suitable coating method, and is heated to remove the solvent in the photosensitive resin composition, thereby forming a photosensitive resin layer. The heating temperature is 70 to 150° C. (more preferably 90 to 150° C.). The heating time is preferably 10 to 600 seconds (more preferably 10 to 180 seconds; further preferably 30 to 120 seconds).

In the method for manufacturing a resist pattern of the present invention, the presence of film(s) or layer(s) other than the photosensitive resin layer is also accepted. Without direct contact of the substrate with the photosensitive resin layer, intervening layer(s) can be interposed. The intervening layer is a layer to be formed between a substrate and a photosensitive resin layer and is referred also to as underlayer film. As the underlayer film, a substrate modifying film, a planarization film, a bottom anti-reflective coating (BARC), an inorganic hard mask intervening layer (silicon oxide film, silicon nitride film and silicon oxynitride film) and an adhesion film can be referred. The planarization film is, for example, SOC. As to the formation of the inorganic hard mask intervening layer, JP 5,336,306 B can be referenced. The intervening layer can be composed of one layer or a plurality of layers. An overlayer film can be formed on the photosensitive resin layer. The overlayer is, for example, a top anti-reflective coating (TARC).

For the layer constitution in the process for manufacturing a resist pattern of the present invention, any publicly known technique can be used in accordance with process conditions. For example, the following layer constitution can be referred.
substrate/photosensitive resin layer
substrate/underlayer film/photosensitive resin layer
substrate/planarization film/photosensitive resin layer
substrate/planarization film/photosensitive resin layer/overlayer film
substrate/planarization film/BARC/photosensitive resin layer
substrate/planarization film/photosensitive resin layer/overlayer film
substrate/planarization film/inorganic hard mask intervening layer/photosensitive resin layer
substrate/planarization film/adhesion film/photosensitive resin layer
substrate/substrate modifying layer/planarization film/photosensitive resin layer
substrate/substrate modifying layer/planarization film/adhesion film/photosensitive resin layer

These layers can be formed as films by coating and thereafter heating and/or exposing to cure, or by employing any publicly known method such as CVD method. These layers can be removed by a publicly known method (etching or the like) and can be patterned using the upper layer as a mask.

One preferred embodiment of the present invention is to apply the photosensitive resin composition directly on the substrate without intervening an intervening layer. Further, in another embodiment of the present invention, TARC is not formed on the photosensitive resin layer.

As another embodiment of the present invention, a thickened resist pattern can be formed by forming a thickened layer on a photosensitive resin layer as in WO2022/129015.

The photosensitive resin layer is exposed through a predetermined mask. When other layers (overlayer film or the like) are also included, they can be exposed together. The wavelength of the radiation (light) used for exposure is not particularly limited, but it is preferable to perform exposure with light having a wavelength of 13.5 to 248 nm. In particular, KrF excimer laser (wavelength: 248 nm), ArF excimer laser (wavelength: 193 nm), extreme ultraviolet ray (EUB, wavelength: 13.5 nm) and the like can be used, and EUB is more preferable. These wavelengths allow a range of ±5%, and preferably a range of ±1%. After the exposure, post exposure bake (PEB) can be performed, if needed. The temperature for PEB is preferably 70 to 150° C. (more preferably 80 to 120° C.) and the heating time is preferably 0.3 to 5 minutes (more preferably 0.5 to 2 minutes).

Thereafter, development is performed with a developer. For the development in the method for manufacturing a resist pattern of the present invention, a 2.38 mass % (±1% is accepted) tetramethylammonium hydroxide (TMAH) aqueous solution is preferably used. Further, a surfactant or the like can also be added to the developer. The temperature of the developer is preferably 5 to 50° C. (more preferably 25 to 40° C.) and the developing time is preferably 10 to 300 seconds (more preferably 20 to 60 seconds). As the developing method, any publicly known method such as paddle development can be used.

As described above, the resist pattern of the present invention includes not only one obtained by exposing/developing a resist film but also one having a wall thickened by further covering a resist film with other layer(s) or film(s).

The resist pattern (the developed photosensitive resin layer) formed up to the above steps is in a non-cleaned state. This resist pattern can be cleaned with the electronic device manufacturing aqueous solution of the present invention. The time for bringing the electronic device manufacturing aqueous solution into contact with the resist pattern, that is, the processing time is preferably 1 second or more. The processing temperature may be also freely determined. The method for bringing the electronic device manufacturing aqueous solution into contact with the resist is also freely selected, and it can be performed, for example, by immersing a resist substrate in the electronic device manufacturing aqueous solution or dropping the electronic device manufacturing aqueous solution on a rotating resist substrate surface.

In the method for manufacturing a resist pattern according to the present invention, the resist pattern after being developed can be cleaned with other cleaning liquid before and/or after the cleaning processing with the electronic device manufacturing aqueous solution. The other cleaning liquid is preferably water, and more preferably pure water (DW, deionized water, or the like). The cleaning before the present processing is useful for cleaning the developer that has adhered to the resist pattern. The cleaning after the present processing is useful for cleaning the electronic device manufacturing aqueous solution. One preferred embodiment of the manufacturing method according to the present invention is a method comprising cleaning the pattern after being developed while replacing the developer by pouring pure water on the resist pattern, and further cleaning the pattern while replacing pure water by pouring the electronic device manufacturing aqueous solution while keeping the pattern immersed in pure water.

The cleaning with the electronic device manufacturing aqueous solution can be carried out by a publicly known method.

It can be performed, for example, by immersing a resist substrate in the electronic device manufacturing aqueous solution, or by dropping the electronic device manufacturing aqueous solution on a rotating resist substrate surface. These methods can be also carried out in appropriate combination thereof.

As one of the conditions under which pattern collapse is likely to occur, there is a place where the distance between a wall and a wall of a resist pattern is the narrowest. At a place where a wall and a wall of a resist pattern are aligned in parallel, this becomes a severe condition. In the present specification, the distance of the interval at the place where the interval is the smallest on one circuit unit is taken as the minimum space size. It is preferable that one circuit unit becomes one semiconductor in a later process. Further, it is also a preferred embodiment that one semiconductor includes one circuit unit in the horizontal direction and a plurality of circuit units in the vertical direction. Of course, unlike the test sample, if the occurrence frequency of the place where the interval between a wall and a wall is narrow is low, the occurrence frequency of defects decreases, so that the occurrence frequency of defective products decreases.

In the present invention, the minimum space size of the resist pattern in one circuit unit is preferably 5 to 30 nm, more preferably 10 to 20 nm, and further preferably 10 to 17 nm.

### Method for Manufacturing a Device

The method for manufacturing a device of the present invention comprises the method for manufacturing a resist pattern using the electronic device manufacturing aqueous solution. Preferably, the method for manufacturing a device according to the present invention further comprises etching using the resist pattern manufactured by the above-mentioned method as a mask and processing a substrate. After processing, the resist film is peeled off, if necessary. Preferably, the device is a semiconductor.

In the manufacturing method of the present invention, the intervening layer and/or the substrate can be processed by etching using the resist pattern as a mask. For etching, any publicly known method such as dry etching and wet etching can be used, and dry etching is more suitable. For example, the intervening layer can be etched using the resist pattern as an etching mask, and the substrate can be etched using the obtained intervening layer pattern as an etching mask to process the substrate. Further, while etching the layer(s) under the resist layer (for example, an intervening layer) using the resist pattern as an etching mask, the substrate can also be uninterruptedly etched. The processed substrate becomes, for example, a patterned substrate. A wiring can be formed on the substrate by utilizing the formed pattern.

These layers can be removed preferably by performing dry etching with O₂, CF₄, CHF₃, Cl₂ or BCl₃, and preferably, O₂ or CF₄ can be used.

As a preferred embodiment, the method for manufacturing a device according to the present invention further comprises forming a wiring on a processed substrate.

Stress which Works to a Resist Wall

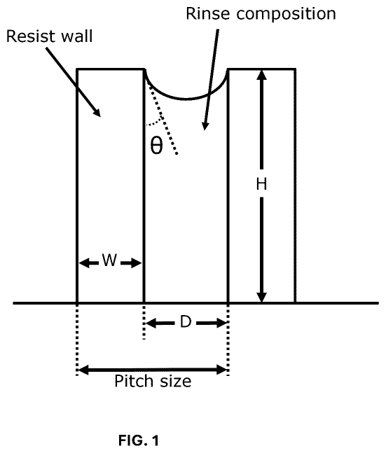

As described in Namatsu et al., Appl. Phys. Lett. 1995 (66), p2655-2657 and schematically illustrated in FIG. 1, the stress which works to a wall during drying rinse can be indicated by the following formula:

$${σ}_{max} = ( 6 γ cos θ / D ) \times {( H / W )}^{2}$$

wherein
   αₘₐₓ: the maximum stress which works to a resist,
   γ: surface tension of rinse
   θ: contact angle,
   D: distance between walls
   H: height of wall, and
   W: width of wall

These lengths can be measured by a known method, for example, SEM photograph.

As can be seen from the above formula, the shorter D or W is, the more stress is caused. In the present specification, “pitch size” means, as described in FIG. 1, one unit of a resist pattern unit sequence having W and D.

This means that the finer (narrower pitch size) the required resist pattern is, the greater the stress which works to the resist pattern becomes. As the pattern becomes finer in this way, the conditions become stricter, and more improvements are required for the electronic device manufacturing aqueous solution (for example, a rinse composition).

The present invention is described below with reference to various examples. Further, the embodiments of the present invention are not limited to these examples.

### Preparation Example of Example 11

Into deionized water, decane sulfonic acid as the sulfonic acid derivative (A) and 3-hexyne 2,5-diol as the hydroxy-containing compound (C) are added so that their concentration become respectively 2,000 ppm and 800 ppm, and the mixture is stirred. Visually, its complete dissolvement is confirmed. This is filtered (pore size=10 nm) to obtain an aqueous solution of Example 11.

### Preparation Examples of Examples 12 to 17, Comparative Examples 11 to 14 and Reference Example 11

In the same manner as in Preparation Example of Example 11 above, using the sulfonic acid derivative (A), hydroxy-containing compound (C), and nitrogen-containing compound (D) as listed in Table 1, aqueous solutions of Examples 12 to 17, Comparative Examples 11 to 14 and Reference Example 11 are prepared so as to have the concentrations as shown in Table 1.

Comparative Example 14 is one, in which deionized water to which nothing is added, is filtered.

TABLE 1
Table 1

| | Component (A) | | Component (C) | | Component (D) | | |
|---|---|---|---|---|---|---|---|
| | | Addition | | Addition | | Addition | Defect |
| | | amount | | amount | | amount | evaluation |
| | Compound | (ppm) | Compound | (ppm) | Compound | (ppm) | (1) |
| Example 11 | A1 | 2,000 | C1 | 800 | — | — | 322 |
| Example 12 | A2 | 1,500 | C2 | 750 | — | — | 320 |
| Example 13 | A3 | 1,000 | C3 | 500 | — | — | 128 |
| Example 14 | A4 | 500 | C4 | 100 | — | — | 133 |
| Example 15 | A5 | 400 | C5 | 500 | — | — | 342 |
| Example 16 | A5 | 1,000 | C3 | 500 | — | — | 65 |
| Example 17 | A4 | 500 | C2 | 500 | Triethylamine | 50 | 221 |
| Comarative | A1 | 200 | comp. C6 | 500 | Triethylamine | 500 | 1840 |
| Example 11 | | | | | | | |
| Comarative | A4 | 300 | comp. C7 | 500 | — | — | 3461 |
| Example 12 | | | | | | | |
| Comarative | — | 0 | C3 | 1,000 | — | — | 1855 |
| Example 13 | | | | | | | |
| Comarative | — | — | — | — | — | — | >10,000 |
| Example 14 | | | | | | | |
| Reference | comp. A6 | 500 | — | — | — | — | 1203 |
| Example 11 | | | | | | | |

### In Tables 1 to 3:

A1: decanesulfonic acid,

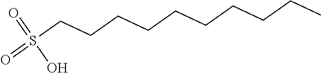

A2: tetradecanesulfonic acid,

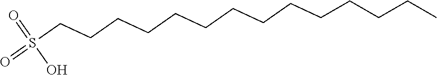 [SMILES: CCCCCCCCCCCCCCS(=O)(=O)O]

A3: dodecylbenzenesulfonic acid,

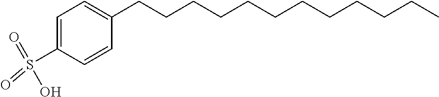 [SMILES: CCCCCCCCCCCCc1ccc(S(=O)(=O)O)cc1]

A4: alkylsulfonic acid mixture (mixture of compounds of the following structure having 13 to 18 carbon atoms),

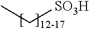

A5: alkylbenzenesulfonic acid mixture (mixture of compounds of the following structure having 13 to 18 carbon atoms in the alkyl chain)

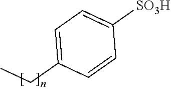

comp. A6: 2-methylhexanoic acid,

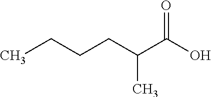

C1: 3-hexyne-2,5-diol,
C2: 2,5-dimethyl-3-hexyne-2,5-diol,
C3: 3,6-dimethyl-4-octyne-3,6-diol,
C4: 4,7-dihydroxy-2,4,7,9-tetramethyl-5-decyne,
C5: cis-2-butene-1,4-diol,
comp. C6: a compound having the following structure, in which R^{a1} is a methyl group, R^{a2} is an isobutyl group, EO is ethylene oxide, PO is propylene oxide, and r11, s11, r21 and s21 are integers that satisfy r11+r21=3.5 and s11+s21=0, respectively,

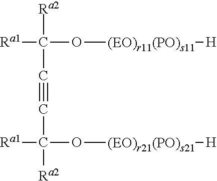

comp. C7: a compound having the above structure, in which R^{a1} is a methyl group, R^{a2} is an isobutyl group, EO is ethylene oxide, PO is propylene oxide, and r11, s11, r21 and s21 are integers satisfy r11+r21=5, s11+s21=2, respectively.

### Defect Evaluation (1)

A silicon substrate is treated with hexamethyldisilazane (HMDS) at 90° C. for 30 seconds. A PHS-acrylate-based chemically amplified type resist for EUV is applied thereon by spin coating and heated on a hot plate at 110° C. for 60 seconds to obtain a resist film having a film thickness of 35 nm. After that, a 2.38 mass % TMAH aqueous solution developer is poured in, and thereafter this state is held for 30 seconds (paddle). In the state that the developer is paddled, water pouring is started, and while rotating the substrate, the developer is replaced with water, this treatment is stopped in the state of being paddled with water. After that, while the aqueous solution of Example 11 is poured into the state of being paddled with water, cleaning is performed while rotating at low speed for 30 seconds to replace the water with the aqueous solution of Example 11. This substrate is rotated at high speed and dried to obtain a cleaned resist film.

The surface of the cleaned resist film is observed using a defect inspection device LS9110 (Hitachi High Technologies), and the number of debris adhered to the resist film surface is counted. The results obtained are shown in Table 1.

For the aqueous solutions of Examples 12 to 17, Comparative Examples 11 to 14 and Reference Example 11, evaluation substrate production is performed in the same manner as the above using the respective aqueous solutions, and the number of debris is counted.

Comparative Example 14 differs from the above-mentioned Example 11 in that the substrate is spin-dried immediately after being paddled with water, but is the same as Example 11 excluding that.

### Preparation Examples of Examples 21 to 27 and Comparative Example 21

In the same manner as in Preparation Example of Example 11 above, using the sulfonic acid derivative (A), the hydroxy-containing compound (C) and the nitrogen-containing compound (D) as shown in Table 2, aqueous solutions of Examples 21 to 27 and Comparative Example 21 are prepared so as to have the concentrations as shown in Table 2.

Comparative Example 21 is one, in which deionized water to which nothing is added, is filtered.

TABLE 2
Table 2

| | Component (A) | | Component (C) | | Component (D) | | Defect | Number | |
|---|---|---|---|---|---|---|---|---|---|
| | | Addition | | Addition | | Addition | eval- | of | Limit |
| | Com- | amount | Com- | amount | Com- | amount | uation | pattern | pattern |
| | pound | (ppm) | pound | (ppm) | pound | (ppm) | (2) | collapse | size |
| Example 21 | A1 | 2,000 | C1 | 800 | — | — | A | 0 | 13.2 |
| Example 22 | A2 | 1,500 | C2 | 750 | — | — | A | 0 | 13.4 |
| Example 23 | A3 | 1,000 | C3 | 500 | — | — | A | 0 | 13.3 |
| Example 24 | A4 | 500 | C4 | 100 | — | — | A | 0 | 13.1 |
| Example 25 | A5 | 400 | C5 | 500 | — | — | A | 0 | 13.5 |
| Example 26 | A5 | 1,000 | C3 | 500 | — | — | A | 0 | 12.9 |
| Example 27 | A4 | 500 | C2 | 500 | Triethyl- | 50 | A | 0 | 12.8 |
| | | | | | amine | | | | |
| Comparative | — | — | — | — | — | — | Ref | 57 | 16.8 |
| Example 21 | | | | | | | | | |

### Defect Evaluation (2)

A silicon substrate is treated with HMDS at 90° C. for 30 seconds. A PHS-acrylate-based chemically amplified type resist for EUV is applied thereon by spin coating and heated on a hot plate at 110° C. for 60 seconds to obtain a resist film having a film thickness of 35 nm. This substrate is exposed using an EUV stepper (NXE: 3400, ASML) through a mask (18 nm, line/space=1:1). After that, PEB is performed on a hot plate at 110° C. for 60 seconds, a 2.38 mass % TMAH aqueous solution developer is poured in, and thereafter this state is held for 30 seconds. In the state that the developer is paddled, water pouring is started, while rotating the substrate, the developer is replaced with water, and this treatment is stopped in the state of being paddled with water. After that, while the aqueous solution of Example 21 is poured into the state of being paddled with water, cleaning is performed while rotating at low speed for 30 seconds to replace the water with the aqueous solution of Example 21. This substrate is rotated at high speed and dried to obtain a cleaned resist pattern.

The number of debris adhered to the surface of the cleaned resist pattern is counted using a defect inspection device UVision 4 (Applied Materials), and the shape of the debris is observed using a wafer defect review and wafer classification system eDR7280 (KLA Tencor). The evaluation is performed according to the following criteria. The results obtained are shown in Table 2.
A: The number of defects is less than 30% of the number of debris in Comparative Example 21.
B: The number of defects is 30% or more and less than 100% of the number of debris in Comparative Example 21.
C: The number of defects is 100% or more and less than 300% of the number of debris in Comparative Example 21.
D: All patterns are dissolved.

For the aqueous solutions of Examples 22 to 27, evaluation substrate production is performed in the same manner as the above using the respective aqueous solutions and the evaluation is performed according to the following criteria.

Comparative Example 21 differs from Example 21 above-mentioned above in that the substrate is spin-dried immediately after being paddled with water, but is the same as Example 21 excluding that.

### Number of Pattern Collapses

A cleaned resist pattern is obtained in the same manner as in the defect evaluation (2).

The number of pattern collapses on the cleaned resist pattern is counted using a defect inspection device UVision 4 (Applied Materials) and a wafer defect review and wafer classification system eDR7280 (KLA Tencor). The results obtained are shown in Table 2.

### Limit Pattern Size

A silicon substrate is treated with HMDS at 90° C. for 30 seconds. A PHS-acrylate-based chemically amplified type resist for EUV is applied thereon by spin coating and heated on a hot plate at 110° C. for 60 seconds to obtain a resist film having a film thickness of 50 nm. This substrate is exposed using an EUV stepper (NXE: 3400, ASML) through a mask (16 nm, line/space=1:1). At this time, the exposure amount is changed so that the line width to be obtained is changed. After that, PEB is performed on a hot plate at 110° C. for 60 seconds, a 2.38 mass % TMAH aqueous solution developer is poured in, and thereafter this state is held for 30 seconds. In the state that the developer is paddled, water pouring is started, while rotating the substrate, the developer is replaced with water, and this treatment is stopped in the state of being paddled with water. After that, while the aqueous solution of Example 21 is poured into the state of being paddled with water, cleaning is performed while rotating at low speed for 30 seconds to replace the water with the aqueous solution of Example 21. This substrate is rotated at high speed and dried to obtain a cleaned resist pattern.

The cleaned resist pattern is observed using a SEM device CG6300 (Hitachi High Technologies), and the line width and the presence or absence of pattern collapse are observed. The minimum line width at which no pattern collapse occurs is taken as the “limit pattern size”. The results obtained are shown in Table 2.

For the aqueous solutions of Examples 22 to 27, the “limit pattern size” is obtained in the same manner as the above using respective aqueous solutions.

Comparative Example 21 differs from Example 21 above in that the substrate is spin-dried immediately after being paddled with water, but is the same as Example 21 excluding that. In this case, since pattern collapse is confirmed with a line width of 16.4 nm, while no collapse is confirmed with a line width of 16.8 nm, the limit pattern size is taken as 16.8 nm.

### Preparation Examples of Examples 31 to 34 and Comparative Example 31

In the same manner as in Preparation Example of Example 11 above, using the sulfonic acid derivative (A), the hydroxy-containing compound (C) and the nitrogen-containing compound (D) as shown in Table 3, aqueous solutions of Examples 31 to 34 and Comparative Example 31 are prepared so as to have the concentrations as shown in Table 2.

Comparative Example 31 is one, in which deionized water to which nothing is added, is filtered.

TABLE 3
Table 3

| | Component (A) | | Component (C) | | Component (D) | | |
|---|---|---|---|---|---|---|---|
| | | Addition | | Addition | | Addition | |
| | | amount | | amount | | amount | LWR |
| | Compound | (ppm) | Compound | (ppm) | Compound | (ppm) | (nm) |
| Example 31 | A3 | 1,000 | C3 | 500 | — | — | 4.2 |
| Example 32 | A4 | 500 | C4 | 100 | — | — | 4.1 |
| Example 33 | A5 | 400 | C5 | 500 | — | — | 4.1 |
| Example 34 | A4 | 500 | C2 | 500 | Triethylamine | 50 | 4.0 |
| Comparative | — | — | — | — | — | — | ※4.1 |
| Example 31 | | | | | | | |

### Evaluation of LWR

Using the same method as in the measurement of the limit pattern size described above, a cleaned resist pattern in the case of having a line width of 16.0 nm is obtained. LWR (Line Width Roughness) of the cleaned resist pattern is measured using a length measurement SEM CG5000. The results are shown in Table 2.

Comparative Example 31 is the measurement result when the line width is 16.8 nm.

What is claimed is:

1. An electronic device manufacturing aqueous solution comprising a sulfonic acid derivative (A);
a solvent (B); and
a hydroxy-containing compound (C),
wherein
the sulfonic acid derivative (A) is represented by the formula (a): 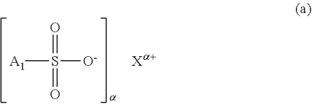
wherein
A₁ is a C₃₋₃₀ hydrocarbon group, and the hydrocarbon group can be substituted with a halogen;
α is 1 or 2; and
X^{α+} is H⁺, NH₄⁺ or an a-valent metal ion,
the solvent (B) comprises water, and
the hydroxy-containing compound (C) is represented by the formula (c): 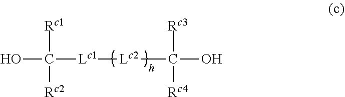
wherein
R^{c1}, R^{c2}, R^{c3} and R^{c4} are each independently hydrogen, fluorine or C₁₋₅ alkyl;
L^{c1} and L^{c2} are each independently C₁₋₂₀ alkylene, C₅₋₂₀ cycloalkylene, C₂₋₄ alkenylene, C₂₋₄ alkynylene or C₆₋₂₀ arylene, and these groups can be substituted with fluorine, C₁₋₅ alkyl or hydroxy; and
h is 0, 1 or 2.

2. The electronic device manufacturing aqueous solution according to claim 1, wherein A₁ is alkyl, phenyl-substituted alkyl or alkyl-substituted phenyl: optionally, the alkyl contained in A₁ is a linear, branched or cyclic alkyl.

3. The electronic device manufacturing aqueous solution according to claim 1, wherein the content of the sulfonic acid derivative (A) is 0.001 to 10 mass % based on the electronic device manufacturing aqueous solution:
optionally, the content of the solvent (B) is 80 to 99.999 mass % based on the electronic device manufacturing aqueous solution;
optionally, the content of water contained in the solvent (B) is 80 to 99.999 mass % based on the electronic device manufacturing aqueous solution; or
optionally, the content of the hydroxy-containing compound (C) is 0.001 to 10 mass % based on the electronic device manufacturing aqueous solution.

4. The electronic device manufacturing aqueous solution according to claim 1, further comprising a nitrogen-containing compound (D):
optionally, the electronic device manufacturing aqueous solution further comprises a surfactant (E).

5. The electronic device manufacturing aqueous solution according to claim 1, further comprising an additive (F):
wherein
the additive (F) comprises an acid, a base, a germicide, an antibacterial agent, a preservative or a fungicide;
optionally, the content of the nitrogen-containing compound (D) is 0.0001 to 1 mass % based on the electronic device manufacturing aqueous solution;
optionally, the content of the surfactant (E) is 0.001 to 5 mass % based on the electronic device manufacturing aqueous solution; or
optionally, the content of the additive (F) is 0.0001 to 10 mass % based on the electronic device manufacturing aqueous solution.

6. The electronic device manufacturing aqueous solution according to claim 1, which is a semiconductor manufacturing aqueous solution:
optionally, the electronic device manufacturing aqueous solution is a semiconductor substrate manufacturing aqueous solution;
optionally, the electronic device manufacturing aqueous solution is a semiconductor substrate manufacturing process cleaning liquid;
optionally, the electronic device manufacturing aqueous solution is a lithography cleaning liquid; or
optionally, the electronic device manufacturing aqueous solution is a resist pattern cleaning liquid.

7. A method for manufacturing a resist pattern using the electronic device manufacturing aqueous solution according to claim 1.

8. A method for manufacturing a resist pattern comprising:
(1) applying a photosensitive resin composition on a substrate with or without one or more intervening layers, to form a photosensitive resin layer;
(2) exposing the photosensitive resin layer to radiation;
(3) developing the exposed photosensitive resin layer; and
(4) cleaning the developed layer with the electronic device manufacturing aqueous solution according to claim 1.

9. The method for manufacturing a resist pattern according to claim 8, wherein the photosensitive resin composition is a chemically amplified photosensitive resin composition, and optionally, exposure is performed using extreme ultraviolet ray.

10. The method for manufacturing a resist pattern according to claim 7, wherein the minimum space size of the resist pattern in one circuit unit is 5 to 30 nm.

11. A method for manufacturing a device, comprising the method for manufacturing a resist pattern according to claim 7.

12. The method for manufacturing a device according to claim 11, further comprising etching using the resist pattern as a mask, and processing a substrate.

13. The method for manufacturing a device according to claim 11, further comprising forming a wiring on a processed substrate.
